(19) United States
(12) Patent Application Publication
(10) Pub. No.: US 2009/0230530 A1
(43) Pub. Date: Sep. 17, 2009

(54) SEMICONDUCTOR DEVICE AND METHOD FOR PRODUCING SEMICONDUCTOR DEVICE

(75) Inventors: Kiyonori OYU, Chuo-ku (JP); Kazuyuki Hozawa, Hino-shi (JP)

Correspondence Address: SUGHRUE MION, PLLC, 2100 PENNSYLVANIA AVENUE, N.W., SUITE 800, WASHINGTON, DC, 20037, US

(73) Assignee: Elpida Memory, Inc., Chuo-ku (JP)

(21) Appl. No.: 12/266,092

(22) Filed: Nov. 6, 2008

(30) Foreign Application Priority Data
Nov. 7, 2007 (JP) 2007-289784

(51) Int. Cl. H01L 23/00; H01L 21/78; H01L 21/50

(52) U.S. Cl. 257/678; 438/113; 257/E21.599; 257/E21.499; 257/E23.001

(57) ABSTRACT

A back side of the silicon semiconductor substrate is roughly ground and is finishing-ground by using a whetstone having a copper content of less than 1 ppm, the back side being an opposite side of a side on which the semiconductor element is formed. The back side of the silicon semiconductor substrate is cleaned by the silicon chemical etching. A part up to depth of 3 nm from the back side of the silicon semiconductor substrate comprises copper of 1×10⁹/cm² or less.

This application is based upon and claims the benefit of priority from Japanese Patent Application No. 2007-289784, filed on Nov. 7, 2007, the disclosure of which is incorporated herein in its entirety by reference.

### BACKGROUND OF THE INVENTION

1. Field of the Invention

The present invention relates to a semiconductor device and a method for producing the semiconductor device.

2. Description of the Related Art

In the related semiconductor device, as illustrated in FIG. 2 of Japanese Patent Laid-Open No. 2005-277116 after desired wafer thickness is obtained by grinding a semiconductor substrate from a back side, in which the semiconductor element is formed on a main surface, then the semiconductor substrate is diced to be a semiconductor chip. Further, the semiconductor chip is packaged.

In this back side grinding step, when the desired wafer thickness is, for example, 100 μm, first, the back side of the semiconductor substrate with the thickness of 700 μm is roughly ground to be 120 μm thick. Next, the back side of the roughly-ground semiconductor substrate is finishing-ground to be 100 μm thick, thereby, the desired thickness is obtained.

When the desired wafer thickness is, for example, 50 μm, first, the back side of the semiconductor substrate with the thickness of 700 μm is roughly ground to be 72 μm thick. Next, the back side of the roughly-ground semiconductor substrate is finishing-ground to be 52 μm thick. After that, in a polishing step, the semiconductor substrate is polishing finishing-ground to be 50 μm thick, thereby, the desired thickness is obtained. Here, the reason why the polishing finishing-grinding is adopted is to prevent the wafer from being easily broken because of the reduced mechanical strength attributed to many grinding damages (micro cracks) induced in the back side after the above finishing-grinding. That is, when the wafer is finishing-ground to be around 52 μm, as compared with the thicker wafer, the semiconductor substrate is more easily broken because of the grinding damage. Thus, if the finishing-grinding is continued without any change, the semiconductor substrate may be broken. Thus, since the polishing finishing-grinding is adopted, it is possible to weaken a force applied to the semiconductor substrate in the grinding, and to prevent the semiconductor substrate from being broken because of such a grinding damage. Meanwhile, a back side grinding method eliminating the micro crack is also described in Japanese Patent Laid-Open No. 2005-85925.

On the other hand, conventionally, Cu (copper) contamination is acknowledged as one of the large causes for reducing the reliability of the semiconductor device. This Cu contamination is induced because Cu is mixed in a producing step for the semiconductor substrate, and in a producing step for the semiconductor device after the semiconductor substrate is prepared. Thus, conventionally, a method for eliminating Cu contained in the semiconductor device has been studied.

Japanese Patent Laid-Open No. 2000-290100 describes a method for eliminating a defect attributed to Cu, which is originally contained in the semiconductor substrate, before it is started to produce the semiconductor device. Japanese Patent Laid-Open No. 2002-25952 describes a method for preventing a cross contamination in which, while the semiconductor device is being produced, metal such as Cu and aluminum, which are configuration components of the semiconductor device itself, is attached to the back side of the semiconductor substrate, and the above attached metal is attached again to another semiconductor substrate through a transportation system.

The semiconductor device becomes a finally-completed product through the following steps: (1) a step of forming a semiconductor element such as a transistor, a wiring, and the like on the semiconductor substrate (hereinafter, may be referred to as “front-end step”); and (2) a step of executing the back side grinding, the dicing, and the packaging of the semiconductor substrate as described in the above background technique (hereinafter, may be referred to as “post step”).

Here, the Cu contamination eliminating method described in Japanese Patent Laid-Open No. 2000-290100 and Japanese Patent Laid-Open No. 2002-25952 is a method for eliminating Cu mixed in the front-end step. Thus, in the methods described in Japanese Patent Laid-Open No. 2000-290100 and Japanese Patent Laid-Open No. 2002-25952, it is not possible to avoid the influence by the Cu contamination in the post step, and the semiconductor device, which is Cu-contaminated in the post step, is packaged with the Cu contamination, so that the Cu contamination has caused a large reduction of product yield.

Particularly, Cu includes such a unique characteristic that a diffusion coefficient in a silicon semiconductor substrate is larger than that of other metals even at low temperature of around 200° C. Thus, an important problem has been to avoid the Cu contamination not only in the front-end step, but also in the post step.

### SUMMARY OF THE INVENTION

The present inventor has tried the following experiment before establishing means for solve the above problem.

(a) First, as illustrated in FIG. 1, a DRAM (Dynamic Random Access Memory) with a memory capacity of 512 megabits is formed as semiconductor element 1 on main surface 3 of silicon semiconductor substrate 2 with thick ness of 700 μm. Meanwhile, in FIG. 1, semiconductor element 1 is typically illustrated in a layered form.

(b) Next, the grinding step is executed from back side 4 of silicon semiconductor substrate 2. First, silicon semiconductor substrate 2 is roughly ground to be 72 μm thick. Next, silicon semiconductor substrate 2 is finishing-ground to be 52 μm thick by using a grinding whetstone with a Cu content of 1000 ppm. After that, silicon semiconductor substrate 2 including Cu by this finishing-grinding is passed through a transport part. Further, by using a normal grinding buff, a polishing step is implemented for back side 4 of silicon semiconductor substrate 2, and silicon semiconductor substrate 2 is polishing finishing-ground to be 50 μm thick.

(c) After that, the dicing and the packaging are executed for silicon semiconductor substrate 2.

(d) After that, a refresh characteristic is estimated. Thereby, such a rate is obtained from a defective rate because of a refresh failure that a semiconductor chip becomes defective. As a result, a defective rate of the semiconductor chip is 250 ppm, in which a back side processing step is executed on the above condition. A crystal condition (existence of grinding damage) of back side 4 of the semiconductor chip, which is a defective product, is checked by the Raman spectroscopic analysis. In addition, the Cu content is checked by using the total reflection X ray fluorescence analysis. In this total reflection X ray fluorescence analysis, a step analyzing method is used, in which back side 4 of silicon semiconductor substrate 2 is analyzed by etching 1 nm by 1 nm. Meanwhile, as the 1 nm by 1 nm etching step, the silicon chemical etching cleaning may be used, as illustrated in exemplary embodiment 1 described below. As a result, the following knowledge has been obtained:

(1) The grinding damage is not included in back side 4 of silicon semiconductor substrate 2;

(2) Cu is contained in an area up to depth of 3 nm from back side 4 of silicon semiconductor substrate 2; and

(3) The Cu content, which is attached to a surface in back side 4 of silicon semiconductor substrate 2, is 1×10¹⁰/cm² to 1×10¹¹/cm².

From the above result, we have now discovered the following facts:

(A) Cu, which is attached to silicon semiconductor substrate 2 because of the whetstone used in the grinding step and a transporting system, is not eliminated in the polishing step; and

(B) In the above (b) back side processing step, the polishing step is executed at the last, so that the grinding damage of back side 4 of silicon semiconductor substrate 2 is eliminated. Thus, Cu, which is contained on the surface of back side 4 of silicon semiconductor substrate 2, or around the surface, is not trapped in the grinding damage of back side 4 of silicon semiconductor substrate 2 even in the following packaging, for example even in a heating process of 180° C. and five hours. As a result of this step, Cu is easily diffused up to main surface 3 of silicon semiconductor substrate 2. As described above, it is considered that Cu reaching a pn junction configured in semiconductor element 1 increases junction leak, and becomes a cause for generating the semiconductor chip with the refresh failure.

The present invention seeks to solve one or more of the above problems, or to improve upon those problems at least in part.

In one embodiment, there is provided a method for producing a semiconductor device, comprising:

(1) preparing a silicon semiconductor substrate comprising a semiconductor element in one side;

(2) roughly grinding from a back side of the silicon semiconductor substrate being an opposite side of a side in which the semiconductor element is formed, by using a whetstone having a copper content of less than 1 ppm;

(3) finishing-grinding from the back side of the silicon semiconductor substrate, by using a whetstone having a copper content of less than 1 ppm;

(4) performing a silicon chemical etching-cleaning to the back side of the silicon semiconductor substrate;

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to form a semiconductor chip, and packaging the diced semiconductor chip.

In another embodiment, there is provided a method for producing a semiconductor device, comprising:

(1) preparing a silicon semiconductor substrate comprising a semiconductor element in one side;

(2) roughly grinding from a back side of the silicon semiconductor substrate being an opposite side of a side in which the semiconductor element is formed, by using a whetstone having a copper content of less than 1 ppm;

(3) finishing-grinding from the back side of the silicon semiconductor substrate, by using a whetstone having a copper content of less than 1 ppm;

(4) performing a polishing finishing-grinding to the back side of the silicon semiconductor substrate by using a grinding buff obtained by adding oxidized metal to chelated grinding buff and hardening the chelated grinding buff.

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to be a semiconductor chip, and packaging the diced semiconductor chip.

In another embodiment, there is provided a method for producing a semiconductor device, comprising:

(1) preparing a silicon semiconductor substrate comprising a semiconductor element in one side;

(2) roughly grinding from a back side of the silicon semiconductor substrate, the back side being an opposite side of a side in which the semiconductor element is formed;

(3) finishing-grinding from the back side of the silicon semiconductor substrate;

(4) performing a silicon chemical etching-cleaning to the back side of the silicon semiconductor substrate so that a part up to depth of 3 nm from the back side of the silicon semiconductor substrate comprises a copper of 1×10⁹/cm² or less;

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to form a semiconductor chip, and packaging the diced semiconductor chip.

In another embodiment, there is provided a method for producing a semiconductor device, comprising:

(1) preparing a silicon semiconductor substrate comprising a semiconductor element in one side;

(2) roughly grinding from a back side of the silicon semiconductor substrate, the back side being an opposite side of a side in which the semiconductor element is formed;

(3) finishing-grinding from the back side of the silicon semiconductor substrate;

(4) performing a polishing finishing-grinding to the back side of the silicon semiconductor substrate, by using a grinding buff obtained by adding oxidized metal to chelated grinding buff and hardening the chelated grinding buff so that a part up to depth of 3 nm from the back side of the silicon semiconductor substrate comprises a copper of 1×10⁹/cm² or less;

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to form a semiconductor chip, and packaging the diced semiconductor chip.

According to the above embodiments, the method for producing the semiconductor device can be provided, in which, when the semiconductor device is packaged, such a Cu distribution is included that the Cu contamination does not reach the semiconductor element such as a transistor in the surface side of the silicon semiconductor substrate. The method for producing the semiconductor device can be provided, in which, the product yield is excellent.

### BRIEF DESCRIPTION OF THE DRAWINGS

The above features and advantages of the present invention will be more apparent from the following description of certain preferred embodiments taken in conjunction with the accompanying drawings, in which:

FIG. 1 is a diagram illustrating one step of a method for producing a related semiconductor device;

FIG. 2 is a diagram illustrating one example of a grinding apparatus used by a producing method of the present invention;

FIG. 3 is a diagram illustrating one example of the grinding apparatus used by the producing method of the present invention;

FIG. 4 is a diagram illustrating one example of the semiconductor device of the present invention;

FIG. 5 is a diagram illustrating one step of the method for producing the semiconductor device of the present invention;

FIG. 6 is a diagram illustrating one step of the method for producing the semiconductor device of the present invention;

FIG. 7 is a diagram illustrating one step of the method for producing the semiconductor device of the present invention;

FIG. 8 is a diagram illustrating one step of the method for producing the semiconductor device of the present invention;

FIG. 9 is a diagram illustrating one step of the method for producing the semiconductor device of the present invention;

FIG. 10 is a diagram illustrating one step of the method for producing the semiconductor device of the present invention;

FIG. 11 is a diagram illustrating one step of the method for producing the semiconductor device of the present invention;

FIG. 12 is a diagram illustrating one step of the method for producing the semiconductor device of the present invention;

FIG. 13 is a diagram illustrating one step of the method for producing the semiconductor device of the present invention;

FIG. 14 is a diagram illustrating one step of the method for producing the semiconductor device of the present invention;

FIG. 15 is a diagram illustrating the semiconductor device of a compared example 1;

FIG. 16 is a diagram illustrating the semiconductor device of a compared example 2; and

FIG. 17 is a diagram illustrating the semiconductor device of a compared example 3.

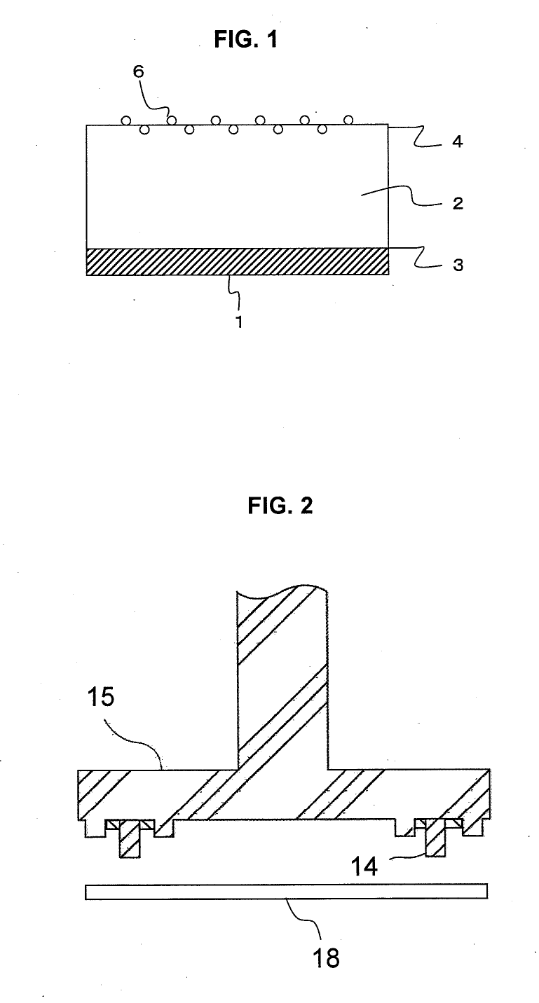

### DESCRIPTION OF SYMBOLS

In the drawings, numerals have the following meanings, 1: semiconductor element, 2: silicon semiconductor substrate, 3: main surface, 4: back side, 5: grinding damage area, 6: copper, 7: thin film, 8: semiconductor chip, 9: die attach film, 10: FBGA substrate, 11: wire, 12: resin, 13: solder ball, 14: whetstone, 15: base, and 18: silicon semiconductor substrate.

### DETAILED DESCRIPTION OF THE PREFERRED EMBODIMENTS

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### 1. A Method for Producing A Semiconductor Device of the First Exemplary Embodiment

The first exemplary embodiment includes the following steps:

(1) preparing a silicon semiconductor substrate comprising a semiconductor element in one side;

(2) roughly grinding from a back side of the silicon semiconductor substrate being an opposite side of a side in which the semiconductor element is formed, by using a whetstone having a copper content of less than 1 ppm;

(3) finishing-grinding from the back side of the silicon semiconductor substrate, by using a whetstone having a copper content of less than 1 ppm;

(4) performing a silicon chemical etching-cleaning to the back side of the silicon semiconductor substrate;

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to form a semiconductor chip, and packaging the diced semiconductor chip.

In the first exemplary embodiment, in the steps (2) and (3), the back side of the silicon semiconductor substrate is roughly ground and is finishing-ground by using the whetstone with the Cu content of less than 1 ppm. Thus, after the finishing-grinding of the step (3), it is possible to cause the silicon semiconductor substrate to contain copper only around the back side, and to cause this copper content itself to be less. In the first exemplary embodiment, as described above, since a small amount of copper is contained only around the back side of the silicon semiconductor substrate, even during heating the silicon semiconductor substrate when the silicon nitride film or the silicon oxynitride film is formed in the step (5), or when the semiconductor chip is packaged in the step (6), such a case is rare that copper is diffused from the back side of the silicon semiconductor substrate up to a semiconductor element side on the surface, and the driving characteristic of the semiconductor element is damaged, so that the product yield can be improved.

Meanwhile, the copper content in the whetstone can be measured by using the total reflection X ray fluorescence analysis. “The whetstone with the copper content of 1 ppm or less” means that, when a part of the whetstone contacting the silicon semiconductor substrate is measured by the above method, the copper content is less than 1 ppm in any area of this part.

### 2. A Method for Producing the Semiconductor Device of the Second Exemplary Embodiment

The second exemplary embodiment includes the following steps:

(1) preparing a silicon semiconductor substrate comprising a semiconductor element in one side;

(2) roughly grinding from a back side of the silicon semiconductor substrate, the back side being an opposite side of a side in which the semiconductor element is formed;

(3) finishing-grinding from the back side of the silicon semiconductor substrate;

(4) performing a silicon chemical etching-cleaning to the back side of the silicon semiconductor substrate so that a part up to depth of 3 nm from the back side of the silicon semiconductor substrate comprises a copper of 1×10⁹/cm² or less;

(5) forming a silicon nitride film or a silicon oxynitride film by executing a heating process or a plasma process at 200° C. or less in ambient atmosphere including at least nitrogen or ammonia for the back side of the silicon semiconductor substrate; and

(6) dicing the silicon semiconductor substrate to form a semiconductor chip, and packaging the diced semiconductor chip.

In the second method for producing the semiconductor device, after the step (4), the copper is locally contained only in a part having depth is 3 nm or less from the back side of the silicon semiconductor substrate. In addition, the copper content is 1×10⁹/cm² or less, which is contained in a part having depth is 3 nm or less from the back side of the silicon semiconductor substrate. Meanwhile, “the copper content is 1×10⁹/cm² or less, which is contained in a part having depth is 3 nm or less from the back side of the silicon semiconductor substrate” means that the copper content is 1×10⁹/cm² or less, which is contained in any area having depth is 3 nm or less from the back side of the silicon semiconductor substrate. Even when the copper is not contained in the inside of the silicon semiconductor substrate, but is attached only on the surface of the back side of the silicon semiconductor substrate, it is assumed that this copper “is contained in a part having depth is 3 nm or less from the back side of the silicon semiconductor substrate”, and it is assumed that the copper content is also 1×10⁹/cm² or less for this copper attached on the surface of the back side of the silicon semiconductor substrate. That is, it is assumed that the copper attached on the back side of the silicon semiconductor substrate is also included in the copper content of the above step (4).

In the second exemplary embodiment, as described above, a small amount of the copper is contained only around the back side of the silicon semiconductor substrate after the step (4). Therefore, even when the semiconductor substrate is heated when the silicon nitride film or the silicon oxynitride film is formed in the step (5), or when the semiconductor chip is packaged in the step (6), such a case is rare that the copper is diffused from the back side of the silicon semiconductor substrate up to a semiconductor element side on the surface, and the driving characteristic of the semiconductor element is damaged, so that the product yield can be improved.

Meanwhile, in the first and second exemplary embodiments, a type of the semiconductor element is not particularly limited, which is provided in one side of the silicon semiconductor substrate. The semiconductor element includes, for example, a planar-type field effect transistor, a fin-type field effect transistor, a DRAM, a capacitor, and a wiring structure.

In the first and second exemplary embodiments, rough grinding” of the step (2) means a step of grinding the silicon semiconductor substrate by using the whetstone so that a grinding rate exceeds 1 μm/s. In the first and second exemplary embodiments, “finishing-grinding” of the step (3) means a step of grinding the silicon semiconductor substrate by using the whetstone so that the grinding rate becomes 1 μm/s or less.

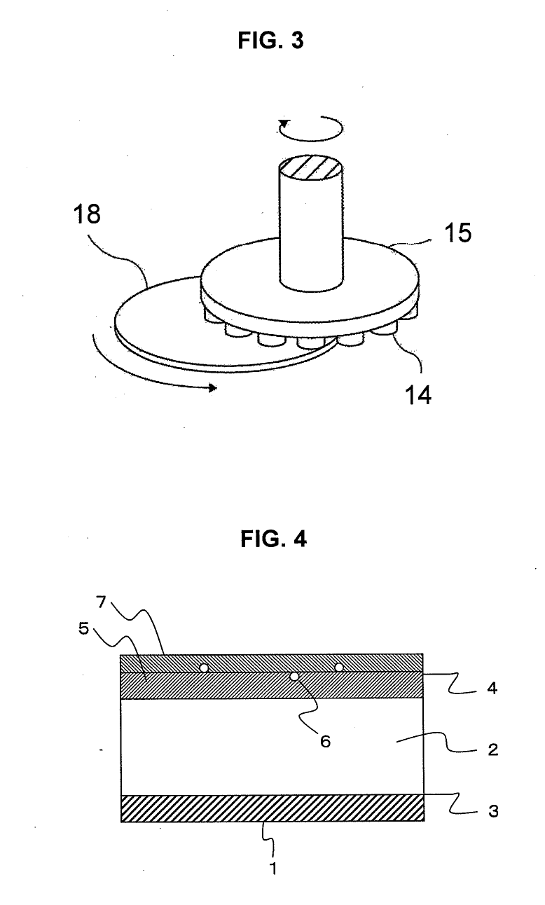

In the first and second exemplary embodiments, the rough grinding of the step (2) and the finishing-grinding of the step (3) can be executed by changing a grinding condition for the same grinding apparatus. FIGS. 2 and 3 illustrate one example of the grinding apparatus for the silicon semiconductor substrate, which is used for the rough grinding and the finishing-grinding. FIG. 2 exemplifies a main cross section view of the grinding apparatus in which whetstone 14 is mounted on base 15. In the rough grinding step and the finishing-grinding step, as exemplified in FIG. 2, the rough grinding and the finishing-grinding can be executed by arranging the whetstone so as to face the silicon semiconductor substrate.

FIG. 3 is a pattern view exemplifying a step of grinding the back side of silicon semiconductor substrate 18 by using the grinding apparatus mounting whetstone 14. Meanwhile, while such an aspect is exemplified in FIG. 3 that each of base 15 and silicon semiconductor substrate 18 is rotated, for example, the following aspects are also included in rotating mean of the present invention: such an aspect that silicon semiconductor substrate 18 is fixed and base 15 is rotated; such an aspect that base 15 is fixed and silicon semiconductor substrate 18 is rotated; such an aspect that silicon semiconductor substrate 18 is fixed and base 15 is rotated around a central axis and the central axis is moved around silicon semiconductor substrate 18; such an aspect that base 15 is fixed and silicon semiconductor substrate 18 is rotated around a central axis which is a perpendicular passing through the center and the central axis is moved around base 15; and the like. When each of base 15 and silicon semiconductor substrate 18 is rotated, rotation directions of base 15 and silicon semiconductor substrate 18 may be the same as each other, or may be reverse to each other, but the reverse directions are preferable.

In the rough grinding step, for example, it is better that base 15 is rotated on a condition of preferably 2000 to 4000 rpm (revolutions per minute), and more preferably 2500 to 3500 rpm (revolutions per minute), in which the whetstone having a particle size in a range of #300 to #500 mesh is mounted, whose. It is better that silicon semiconductor substrate 18 is rotated on a condition of preferably 100 to 500 rpm (revolutions per minute), and more preferably 200 to 300 rpm (revolutions per minute). It is better that the grinding rate for semiconductor substrate 18 is preferably more than 1 μm/s, and equal to or less than 10 μm/s, and more preferably 3 to 8 μm/s.

In the finishing-grinding step, for example, it is better that base 15 is rotated on a condition of preferably 2000 to 4000 rpm (revolutions per minute), and more preferably 2500 to 3500 rpm (revolutions per minute), in which the whetstone having a particle size in a range of #3000 to #4000 mesh is mounted. It is better that silicon semiconductor substrate 18 is rotated on a condition of preferably 100 to 500 rpm (revolutions per minute), and more preferably 200 to 300 rpm (revolutions per minute). It is better that the grinding rate for silicon semiconductor substrate 18 is preferably 0.1 to 1 μm/s, and more preferably 0.3 to 0.8 μm/s.

When this silicon semiconductor substrate 18 is ground, it is better that silicon semiconductor substrate 18 is normally ground eliminating grinding dust by flowing pure water on silicon semiconductor substrate 18. The purity of this pure water is not normally restricted for the purity of the pure water used for producing the silicon semiconductor substrate. The flow rate of the pure water is normally in a range of preferably 10 to 40 litter/minute, and more preferably 20 to 30 litter/minute. After the rough grinding and the finishing-grinding are completed, water attached on silicon semiconductor substrate 18 can be eliminated by spraying gas such as dry air with foreign substance eliminated on silicon semiconductor substrate 18.

It is better that the thickness of roughly-ground silicon semiconductor substrate 18 is in a range of preferably 50 to 300 μm, more preferably 60 to 200 μm, and further preferably 70 to 100 μm. It is better that the thickness of finishing-ground silicon semiconductor substrate 18 is in a range of preferably 20 to 200 μm, more preferably 30 to 100 μm, and further preferably 50 to 80 μm.

In the step (4) of the first and second exemplary embodiments, the silicon configured in silicon semiconductor substrate 18 is chemically etched. This silicon chemical etching is executed to eliminate, by cleaning, the copper attached to the back side of silicon semiconductor substrate 18. In this case, silicon semiconductor substrate 18 is not ground, and the thickness is not changed, or is not almost changed.

In the step (6) of the first and second exemplary embodiments, first, silicon semiconductor substrate 18 is diced to be a plurality of the semiconductor chips. After that, in the packaging step, the semiconductor chip is attached on a substrate such as the FBGA, and in a wire bonding step, a wiring is provided by using a gold wire, or the like between silicon semiconductor substrate 18 and the substrate such as the FBGA. Next, the semiconductor chip mounted on the substrate such as the FBGA is sealed with sealing resin, next, the after cure is executed. As a result, a sealing step can be executed. A condition for this sealing step is typically 170 to 190° C., 10 hours, preferably a range of 2 to 6 hours.

The sealing resin is not specifically restricted, and the commercially available sealing resin can be used, and for example, the epoxy resin composition is used, whose main components are epoxy resin, phenol-based hardener, hardening accelerator, and filler such as silica. Next, a solder ball can be attached in a reflow step, thereby, a package can be finally obtained.

Meanwhile, in the first and second exemplary embodiments, a transporting step may be included between each step, which transports silicon semiconductor substrate 18 from a predetermined area to another predetermined area. In this transporting step, during the transporting, impurity such as Cu may be diffused in silicon semiconductor substrate 18, or may be attached to the back side of silicon semiconductor substrate 18. However, since an amount of this impurity such as Cu diffused or attached to silicon semiconductor substrate 18 is small, the impurity does not influence the advantageous effect of the invention for the first and second exemplary embodiments. Further, in the second exemplary embodiment, the transporting step is executed before the cleaning step (4) by the silicon chemical etching cleaning. In the step (4), the copper content is controlled to be 1×10⁹/cm² or less, which is locally contained in a part up to depth of 3 nm from the back side of silicon semiconductor substrate 18.

The existence of “grinding damage” (micro crack) in the semiconductor chip can be confirmed by checking a crystal condition in silicon semiconductor substrate 18 with the Raman spectroscopic analysis. Specifically, a laser is radiated, whose exited light wave length for the Raman spectroscopy is 364 nm, the Raman shift dependence of the scattered light intensity is obtained, and when a half-value width of a scattered light intensity distribution (typically, the Lorentz distribution) is 4 cm⁻¹ or more, it is determined that the grinding damage is included.

### Exemplary Embodiment 1

### (Structure)

The semiconductor of exemplary embodiment 1 of the present invention will be described by using FIG. 4. FIG. 4 illustrates the semiconductor chip having thickness of 100 μm just before the packaging. In this semiconductor chip, the DRAM is provided as semiconductor element 1 on main surface 3 of silicon semiconductor substrate 2. Meanwhile, in FIG. 4, semiconductor element 1 is typically illustrated in a layered form. Grinding damage area 5 with depth of 10 to 100 nm is formed in back side 4 of silicon semiconductor substrate 2.

In this semiconductor chip, as described later, after the silicon chemical etching step (4), Cu 6 with a content of 5×10⁸/cm² is locally contained in a part having depth up to 2 nm from back side 4 of silicon semiconductor substrate 2. Back side 4 of silicon semiconductor substrate 2 is covered by thin film 7 made of the silicon nitride film with thickness of 5 nm.

### (Producing Method)

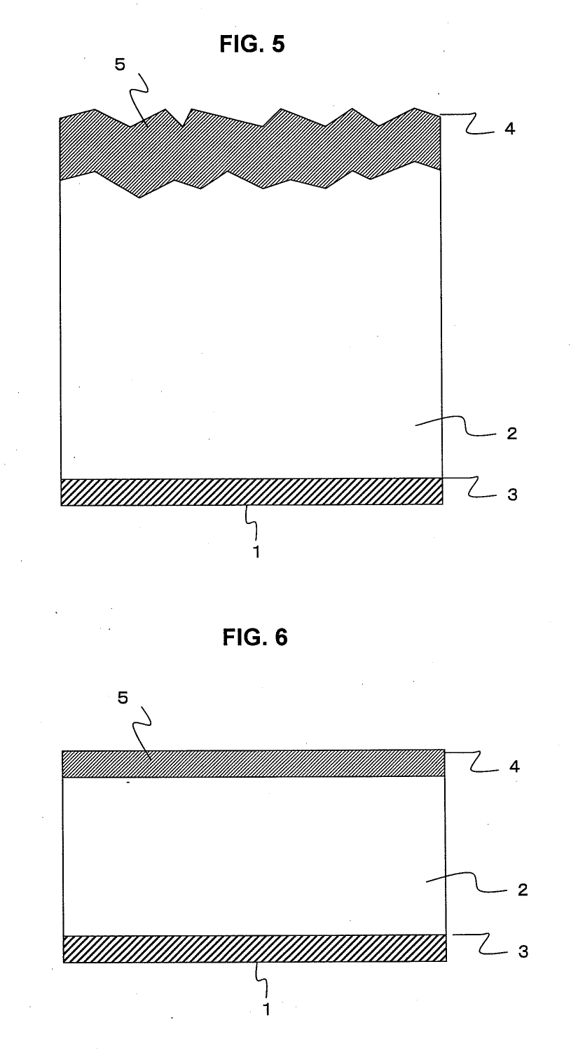

The method for producing the semiconductor device of exemplary embodiment 1 will be described below. First, as illustrated in FIG. 5, a protection substrate (not-illustrated) made of quartz was provided on semiconductor element 1 of silicon semiconductor substrate 2 in which the DRAM was formed as semiconductor element 1 on main surface 3 (step (1)). Next, silicon semiconductor substrate 2 is roughly ground from back side 4 to be 120 μm thick (step (2)). Meanwhile, the whetstone used for the rough grinding was obtained by resin-bonding mesh-like #400 diamond abrasive coating, and the whetstone with the Cu content of 0.5 ppm was used.

Next, as illustrated in FIG. 6, silicon semiconductor substrate 2 was finishing-ground to be 100 μm thick (step (3)). This whetstone used for the finishing-grinding was obtained by resin-bonding mesh #2000 diamond abrasive coating, and the whetstone with the Cu content of 0.2 ppm was used.

As a result of checking a grounded surface of silicon semiconductor substrate 2 by the Raman spectroscopic analysis after this finishing grinding, grinding damage 5 with depth of 10 to 100 nm was formed on the grounded surface. As a result of checking back side 4 of silicon semiconductor substrate 2 passing through the transport part after the finishing grinding by the total reflection X ray fluorescence analysis, the Cu content of 1×10¹⁰/cm² was detected.

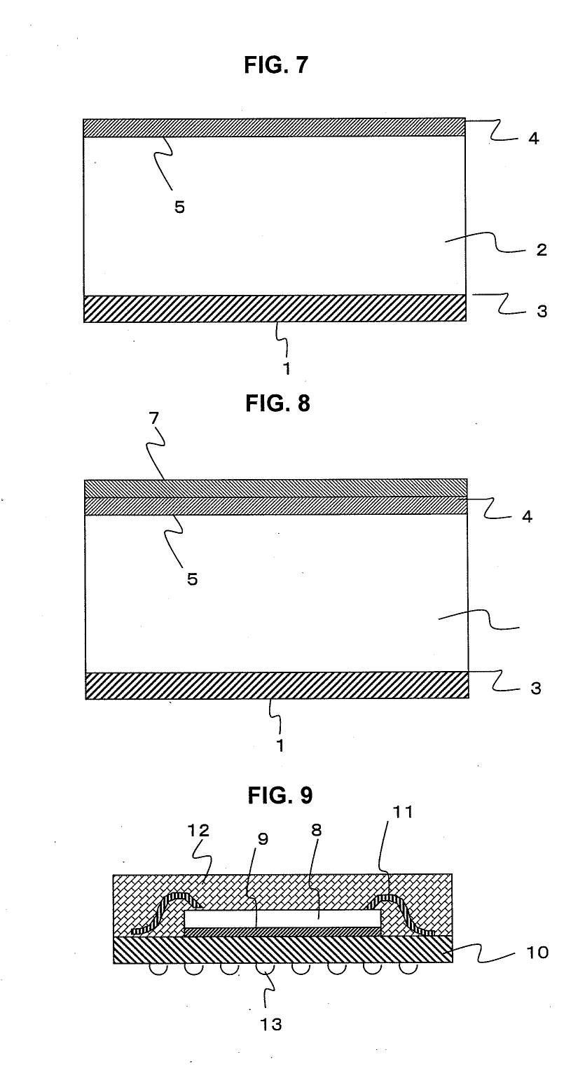

To eliminate Cu detected as described above, as illustrated in FIG. 7, the silicon chemical etching cleaning was executed to silicon semiconductor substrate 2 with cleaning solution obtained by adding dilute hydrofluoric acid to the ozone-added pure water by using a back side spin cleaning apparatus (step (4)). Meanwhile, the silicon chemical etching cleaning was executed on the following condition. After dilute solution, in which hydrofluoric acid (HF)/pure water (H₂O) was 1/100, was supplied for eight seconds to back side 4 of silicon semiconductor substrate 2 rotating at 150 rpm, the 15 ppm ozone-contained pure water was supplied for 10 seconds. Next, after the pure water was supplied for 15 seconds the spin drying was executed by increasing a rotation rate to 1000 rpm. In this cleaning step, silicon semiconductor substrate 2 was etched by around 1 nm, Cu was locally contained in an area up to depth of 2 nm from back side 4 of silicon semiconductor substrate 2, and the Cu content became 5×10⁸/cm². As a result, it is understood that Cu, which is attached to back side 4 of silicon semiconductor substrate 2 in the transporting system, is eliminated.

Meanwhile, in the present exemplary embodiment, while the above condition is used as the condition for the silicon chemical etching cleaning of the step (4), if the following preferable condition range is set, a desired etching amount and desired Cu-eliminated effect are obtained for silicon semiconductor substrate 2.

First, it is better that the rotation rate for silicon semiconductor substrate 2 is selected from a range of 100 to 200 rpm when the dilute solution is supplied, the ozone-contained pure water is supplied, and the pure water is supplied as described above. In the present exemplary embodiment, 150 rpm was selected as the rotation rate in which the etching amount of silicon semiconductor substrate 2 is good in uniformity.

It is better that composite of the above dilute solution is selected from a range of 1/200 to 1/50 for hydrofluoric acid (HF)/pure water (H₂O). In the present exemplary embodiment, a composition ratio 1/100 was selected as depending on a supplying time, that is, an eliminating time for a natural oxidized film. Meanwhile, to completely eliminate the natural oxidized film, when the composition ratio 1/200 is selected, 20 seconds are necessary for the supplying time, and when the composition ratio 1/50 is selected, four seconds are necessary for the supplying time. When the supplying time is 20 seconds, a series of the above cleaning times are increased, and when the supplying time is four seconds, the etching amount of silicon semiconductor substrate 2 is degraded in the uniformity. Thus, in the present exemplary embodiment, the composition was selected, in which the natural oxidized film is completely eliminated for eight seconds as the supplying time. Meanwhile, a supplied-amount of the above dilute solution is preferably in a range of 0.5 to 0.7 litter/minute.

An ozone content in the ozone-contained pure water is preferably selected from in a range of 10 ppm to 30 ppm. When the ozone content is small, a desired etched amount for silicon semiconductor substrate 2 is not obtained, so that it is necessary to increase the supplying time. When the ozone content is large, the etching amount of silicon semiconductor substrate 2 is degraded in the uniformity. Thus, in the present exemplary embodiment, 15 ppm was selected.

A range of five seconds to 20 seconds is preferable as the supplying time for this ozone-contained pure water, and from the view point for the uniformity of the etching amount of silicon semiconductor substrate 2 and a series of the above cleaning times, in the present exemplary embodiment, the supplying time of 10 seconds was selected. Meanwhile, the supplied-amount of the above ozone-contained pure water was caused to be around 1.5 litter/minute.

Further, a supplying time of the pure water for eliminating the above solution is preferably selected from a range of 10 seconds to 30 seconds in consideration of the character for eliminating the solution as depending on an amount of the supplied pure water. In the present exemplary embodiment, since the pure water was supplied at around 2 litter/minute, the solution could be completely eliminated for around 10 seconds, and the supplying time of the pure water was caused to be 15 seconds to have an enough time.

The rotation rate of silicon semiconductor substrate 2 for the spine-drying is preferably selected from a range of 500 rpm to 2000 rpm. When this rotation rate is low, a time for eliminating the pure water becomes longer, and when the rotation rate is high, the time for eliminating the pure water becomes shorter, however, a rotation load becomes larger, so that the rotation rate can be arbitrarily selected in consideration of a series of the above cleaning times. In the present exemplary embodiment, 1000 rpm was selected so that the time for eliminating the pure water does not become longer, and the rotation load does not become larger.

By repeating a series of the above cleanings, the etched amount can be arbitrarily selected for silicon semiconductor substrate 2. In the present exemplary embodiment, since Cu could be sufficiently eliminated by the etching of 1 nm, the number of the repeating was caused to be one time, however, even when a deep area is also Cu-contaminated, the repeating may be executed several times.

Meanwhile, in the step (4), the following cleanings may be also executed along with the above silicon chemical etching cleaning: the bell clean brush cleaning; the two-fluid jet cleaning; or the ice scrubber cleaning. Silicon semiconductor substrate 2 is not etched by the cleaning other than the silicon chemical etching cleaning. In the present exemplary embodiment, by combining such cleanings, Cu can be effectively cleaned.

After that, as illustrated in FIG. 8, thin film 7 composed with the silicon nitride film having film thickness of 5 nm was formed by plasma-radiating back side 4 of silicon semiconductor substrate 2 in ambient atmosphere including nitrogen at room temperature (step (5)). Meanwhile, in this step (5), the plasma process may be executed in the ambient atmosphere including ammonia instead of nitrogen. The silicon oxynitride film can be also formed by executing the plasma process by mixing oxygen in the ambient atmosphere including such nitrogen or ammonia.

Here, as a condition for the preferable plasma radiation, the plasma is preferably excited in such a condition that nitrogen is supplied, whose amount is the same as that of argon, so as to maintain a degree of vacuum to be 500 Pa, and the excited plasma is preferably radiated to back side 4 of silicon semiconductor substrate 2. In the present exemplary embodiment, the silicon nitride film with thickness of 5 nm was formed by plasma-radiating for around five minutes.

Meanwhile, it is preferable to select a range of 100 Pa to 500 Pa as the degree of vacuum so that plasma intensity becomes a desired value. In the present exemplary embodiment, 500 Pa was selected so that the plasma intensity became large.

When gas including ammonia instead of nitrogen, specifically, gas with composition of NH₃/He=1/10 is used, and when the plasma is excited at the above degree of vacuum, and the excited plasma is radiated to back side 4 of silicon semiconductor substrate 2, the silicon nitride film with thickness of 5 nm can be formed for around two minutes. Further, oxygen is supplied in the same amount as that of gas including nitrogen or ammonia roughly, the silicon oxynitride film can be formed.

By forming thin film 7 in back side 4 of silicon semiconductor substrate 2 from the silicon nitride film or the silicon oxynitride film, Cu can be effectively captured in this thin film 7, which is contained, before thin film 7 is formed, in the inside around back side 4 of silicon semiconductor substrate 2. It is possible to prevent Cu attached to back side 4 of silicon semiconductor substrate 2 from being diffused to the inside of silicon semiconductor substrate 2, after thin film 7 is formed.

Here, when a silicon oxidized film is used as thin film 7, since interfacial stress of thin film 7 is small, a capability for capturing Cu is small, and a diffusion rate of Cu becomes large in the film. Thus, the silicon oxidized film is not suitable for thin film 7. Since the interfacial stress with silicon is increased, and the capability for capturing Cu is increased, and Cu is suppressed to be diffused in the film, it is preferable to use the silicon nitride film as thin film 7.

Meanwhile, the remote plasma CVD (Chemical Vapor Deposition) method may be used as a method for forming thin film 7 instead of the above method for plasma-radiating in the ambient atmosphere including nitrogen. In this remote plasma CVD method, monosilane gas (SiH₄) or disilane gas (Si₂H₆) is supplied, as silicon material, to back side 4 of silicon semiconductor substrate 2, and nitrogen (N₂) gas or ammonia (NH₃) gas is used as nitride agent material for the remote plasma excitation, thereby, an exciting reaction is generated by the remote plasma, and the silicon nitride film can be deposited. Since the remote plasma CVD method is a plasma reaction, the precise film can be deposited at low temperature of 100° C. or less.

Meanwhile, the film thickness of the silicon nitride film, which can be formed by the plasma nitriding method, is limited to around 5 nm, and the thicker thin film 7 can not be formed. Thus, when the silicon nitride film with thickness of 10 nm is desired, for example, after the silicon nitride film with thickness of 5 nm is formed by the plasma nitriding method, next, a laminated film may be formed by depositing the remaining silicon nitride film with thickness of 5 nm by the remote plasma CVD method. When the silicon oxynitride film is used as thin film 7, it is enough that oxygen (O₂) gas or dinitrogen monooxide (N₂O) gas may be mixed in the ambient atmosphere.

In this remote plasma CVD method, for example, in such a condition that the degree of vacuum is the same as that of the above plasma radiation, and argon gas and the above NH₃/He gas are supplied, whose amounts are the same as each other, by introducing, for about one minute, the monosilane obtained by diluting with a small amount (around 1/100 of the above argon gas flow rate) of He to back side 4 of silicon semiconductor substrate 2, the silicon nitride film with thickness of 5 nm can be laminated.

Next, after the protection substrate is eliminated, silicon semiconductor substrate 2 was diced to be the semiconductor chip, and the semiconductor chip is FBGA-packaged as illustrated in FIG. 9 (step (6)). In this step (6), first, die attach film 9 was attached to a back side of semiconductor chip 8, and the other side of die attach film 9 is attached to FBGA substrate 10.

In such a case, to increase the adhesiveness of die attach film 9, FBGA substrate 10 was attached in such a condition that temperature of semiconductor chip 8 was 150° C. Next, after wire 11 was bonded, the whole of a resulting structure was sealed with resin 12 at 175° C. After this resin sealing, the whole of a resulting structure was baked at 175° C. for around five hours to harden the resin. Finally, solder ball 13 was fitted on a back side (the opposite side to a semiconductor chip 8 side) of FBGA substrate 10. Meanwhile, this fitting for solder ball 13 was executed by the solder reflow of 260° C. and around 10 seconds. As described above, the semiconductor device of the above exemplary embodiment 1 was produced.

### (Advantageous Effect)

According to exemplary embodiment 1, after the step (4), in such a condition that grinding damage 5 is included in back side 4 of silicon semiconductor substrate 2, the content of Cu 6, which is locally contained in a part up to depth of 2 nm from back side 4 of silicon semiconductor substrate 2, can be reduced to 5×10⁸/cm². Thus, it is possible to neglect the influence of the Cu contamination to silicon semiconductor substrate 2 in a back surface grinding step. Since back surface 4 of silicon semiconductor substrate 2 is covered with thin film 7 made of the silicon nitride film, when the packaging is executed, thin film 7 can prevent Cu from entering to back side 4 of silicon semiconductor substrate 2.

As a result, an information maintaining characteristic for the packaged DRAM can be maintained favorable, and a defective rate of the semiconductor chip, in which a refresh fault is induced after the packaging, can be caused to be around 5 ppm. That is, it is understood that, as compared with a semiconductor device produced by the related production method and silicon chemical-etched has the Cu content of 1×10¹⁰/cm² and the defective rate of 500 ppm, the production yield of the exemplary embodiment 1 is largely improved.

### Exemplary Embodiment 2

### (Structure)

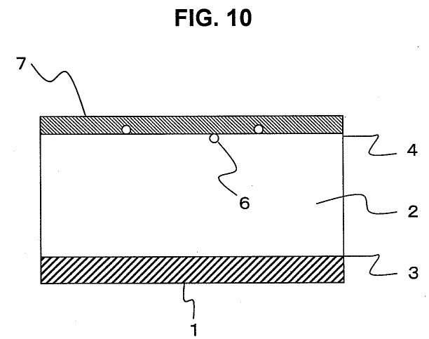

The semiconductor device of exemplary embodiment 2 of the present invention will be described by using FIG. 10. FIG. 10 illustrates the semiconductor chip with thickness of 50 μm just before the packaging. In this semiconductor chip, the DRAM is provided as semiconductor element 1 on main surface 3 of silicon semiconductor substrate 2. Meanwhile, in FIG. 10, semiconductor element 1 is typically illustrated in a layered form. In the present exemplary embodiment, the grinding damage is not formed on a grinding surface of back side 4.

In this semiconductor chip, as described later, after the polishing finishing-grinding step, Cu 6 with the content of 1×10⁸/cm² is locally contained in a part up to depth of 3 nm from back side 4 of silicon semiconductor substrate 2. Back side 4 of silicon semiconductor substrate 2 is covered with thin film 7 made of the silicon nitride film with the film thickness of 5 nm.

### (Producing Method)

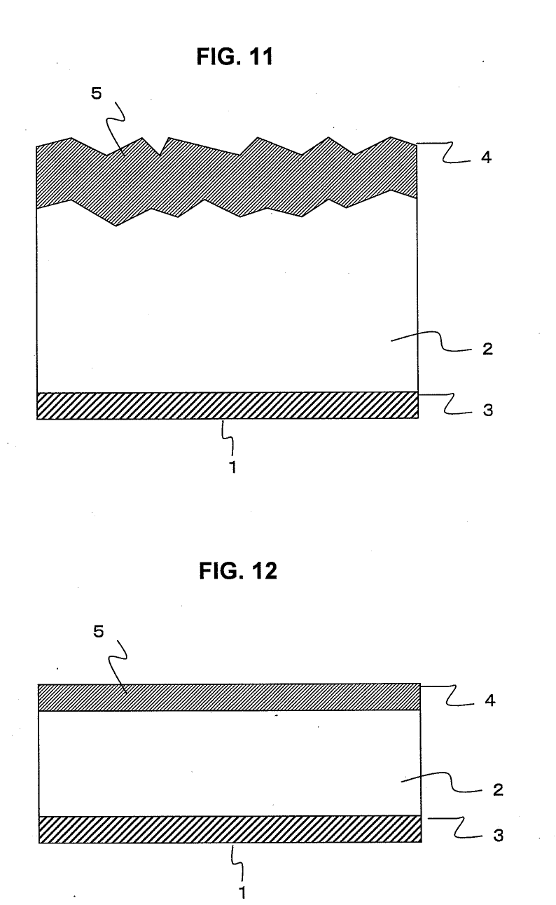

The method for producing exemplary embodiment 2 will be described below. First, as illustrated in FIG. 11, the protection substrate (not-illustrated) made of quartz was provided on semiconductor element 1 of silicon semiconductor substrate 2 in which the DRAM is formed as semiconductor element 1 on main surface 3 (step (1)). Next, back side 4 of silicon semiconductor substrate 2 was roughly ground to be 72 μm thick (step (2)). The whetstone used for this rough grinding was obtained by resin-bonding diamond abrasive coating of mesh #400, and the copper content was 0.5 ppm.

Next, as illustrated in FIG. 12, silicon semiconductor substrate 2 was finishing-ground to be 52 μm thick (step (3)). The whetstone used for this finishing-grinding was obtained by resin-bonding diamond abrasive coating of mesh #2000, and the copper content was 0.2 ppm.

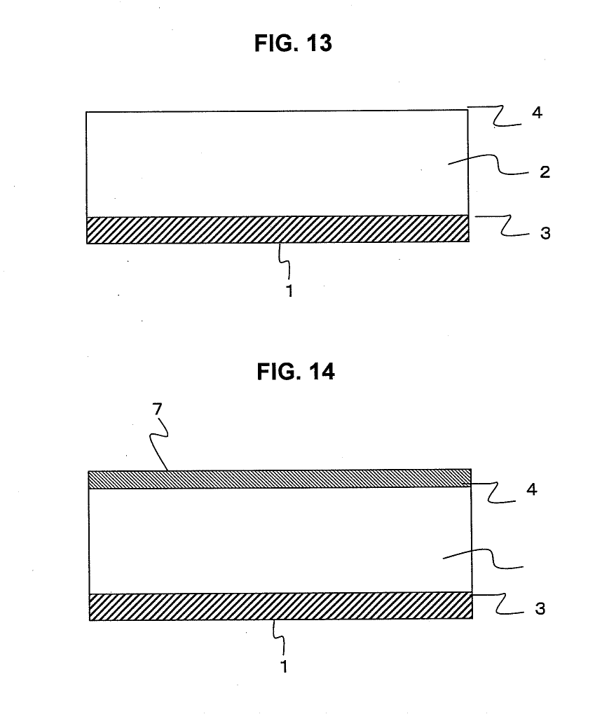

Next, as illustrated in FIG. 13, silicon semiconductor substrate 2 was polishing finishing-ground to be 50 μm thick. In this polishing finishing-grinding, by grinding back side 4 of silicon semiconductor substrate 2, the grinding damage could be eliminated, which was included in back side 4 of silicon semiconductor substrate 2.

Meanwhile, a favorable condition for the polishing finishing-grinding includes a condition that a wheel with the below grinding buff is rotated in a range of 1000 rpm to 3000 rpm, and silicon semiconductor substrate 2 is rotated in a range of 100 rpm to 500 rpm. When the polishing finishing-grinding is executed under such conditions, a polishing rate (a rate at which semiconductor substrate 2 is ground) becomes in a range of 3 nm/s to 20 nm/s. In the present exemplary embodiment, from a viewpoint of a life of the grinding buff and a polishing time, 12 nm/s was selected as the polishing rate, the rotation rate of the wheel with the grinding buff was set to be 1500 rpm so that the polishing rate becomes 12 nm/s, and the rotation rate of semiconductor substrate 2 was set to be 200 rpm.

The grinding buff used for this polishing finishing-grinding is obtained by mixing and hardening oxidized metal including oxidized celium in the chelated grinding buff. A main component of this grinding buff is porous solid with a continuous air hole using polyvinyl alcohol as a material. The chelating process for this grinding buff can be executed by mixing edetic acid powder in the above porous solid. Further, the grinding buff is hardened by mixing fine powder of oxidized celium, and the like in the above porous solid.

After that, as illustrated in FIG. 14, by plasma-radiating back side 4 of semiconductor substrate 2 at room temperature and in nitrogen atmosphere, thin film 7 made of the silicon nitride film with the film thickness of 5 nm was formed (step (5)). Next, after the protection substrate was eliminated, the wafer was diced to be the semiconductor chip, and the FBGA packaging was executed as illustrated in FIG. 9 of exemplary embodiment 1 (step (6)). In this packaging step, the process was executed like exemplary embodiment 1.

### (Advantageous Effect)

In exemplary embodiment 2, after the polishing finishing-grinding step, in such a condition that grinding damage 5 is not included on the grinding surface of back side 4, the content of Cu 6, which is locally contained in a part up to depth of 2 nm from back side 4 of silicon semiconductor substrate 2, can be reduced to 1×10⁸/cm². Thus, in the final product, the influence of the Cu contamination because of the grinding step can be neglected. Since back side 4 of silicon semiconductor substrate 2 is covered by thin film 7 made of the silicon nitride film with thickness of 5 nm, thin film 7 can prevent the copper from reaching back side 4 of silicon semiconductor substrate 2 when the semiconductor chip is packaged.

Since the chelated grinding buff used for the polishing finishing-grinding can capture a Cu ion, the grinding buff can capture the Cu ion, which is locally included in silicon semiconductor substrate 2, when the polishing finishing-grinding is executed, and can effectively eliminate the Cu ion from the inside of silicon semiconductor substrate 2. Further, when the normal grinding buff is used, since silicon semiconductor substrate 2 is charged because of friction by the polishing finishing-grinding, the Cu ion can not be sufficiently captured. However, in the present exemplary embodiment, since the oxidized metal is mixed in the grinding buff, it is possible to prevent silicon semiconductor substrate 2 from being charged, and to facilitate the Cu ion to be captured. As described above, in the present exemplary embodiment, by using the chelated grinding buff, Cu could be more effectively eliminated.

As a result, the information maintaining characteristic for the packaged DRAM can be maintained favorable, and the defective rate of the semiconductor chip, in which the refresh fault is induced after the packaging, is around 3 ppm, so that it is understood that the production yield is largely improved.

### Exemplary Embodiment 3

### (Structure)

FIG. 10 illustrates the semiconductor chip with thickness of 50 μm just before the packaging. In this semiconductor chip, the DRAM is provided as semiconductor chip 1 on main surface 3 of silicon semiconductor substrate 2. Meanwhile, in FIG. 10, semiconductor element is typically illustrated in a layered form. In the present exemplary embodiment, the grinding damage is not formed on the grinding surface of back side 4.

In this semiconductor chip, as described later, after the silicon chemical etching step (4), Cu 6 with the content of 5×10⁷/cm² is locally contained in a part up to depth of 3 nm from back side 4 of silicon semiconductor substrate 2, and back side 4 of silicon semiconductor substrate 2 is covered by thin film 7 made of the silicon oxynitride film with the film thickness of 5 nm.

(Producing Method)

The method for producing the semiconductor device of exemplary embodiment 3 is as follows. First, as illustrated in FIG. 11, the protection substrate (not-illustrated) made of quartz was provided on semiconductor element 1 of silicon semiconductor substrate 2 in which semiconductor element 1 was formed on main surface 3 (step (1)). Next, back side 4 of silicon semiconductor substrate 2 was roughly ground to be 72 μm thick (step (2)). The whetstone used for this rough grinding was obtain by resin-bonding diamond abrasive coating of mesh #400, and the copper content was 0.5 ppm.

Next, as illustrated in FIG. 12, silicon semiconductor substrate 2 was finishing-ground to be 52 μm thick (step (3)). The whetstone used for this finishing-grinding was obtained by resin-bonding diamond abrasive coating of mesh #2000, and the copper content is 0.2 ppm.

Next, as illustrated in FIG. 13, silicon semiconductor substrate 2 was polishing finishing-ground to be 50 μm thick. The grinding buff used for this polishing finishing-grinding was obtained by mixing and hardening oxidized metal in the chelated grinding buff described in exemplary embodiment 2. In this polishing finishing-grinding, by grinding back side 4 of silicon semiconductor substrate 2, it was possible to eliminate the grinding damage included in back side 4 of silicon semiconductor substrate 2. Next, since the polishing grinded surface was silicon chemical etching-cleaned like exemplary embodiment 1, copper 6 attached to back side 4 was eliminated (step (4)).

After that, as illustrated in FIG. 14, by applying the plasma process to back side 4 of semiconductor substrate 2 at the room temperature and in the oxygen and nitrogen-mixed ambient atmosphere, the silicon oxynitride film 7 with the film thickness of 5 nm was formed (step (5)). Next, after the protection substrate was eliminated, semiconductor substrate 2 was diced to be the semiconductor chip, and the FBGA packaging was executed as illustrated in FIG. 9 of exemplary embodiment 1 (step (6)). This packaging step was executed like exemplary embodiment 1.

### (Advantageous Effect)

In exemplary embodiment 3, after the step (4), in such a condition that grinding damage 5 is not included in back side 4 of silicon semiconductor substrate 2, the content of copper 6, which is locally contained in a part up to depth of 2 nm from back side 4 of silicon semiconductor substrate 2, is reduced to 5×10⁷/cm². Thus, the influence of the copper contamination because of the grinding for silicon semiconductor substrate 2 can be almost neglected. Since back side 4 of silicon semiconductor substrate 2 is covered by thin film 7 made of the silicon oxynitride film with thickness of 5 nm, this thin film 7 can prevent the copper from reaching back side 4 of silicon semiconductor substrate 2 when the semiconductor device is packaged.

As a result, the information maintaining characteristic for the packaged DRAM can be maintained favorable, and the defective rate of the semiconductor chip, in which a refresh fault is induced after the packaging, can be caused to be around 2 ppm, so that it is understood that the production yield is largely improved.

### Compared Example 1

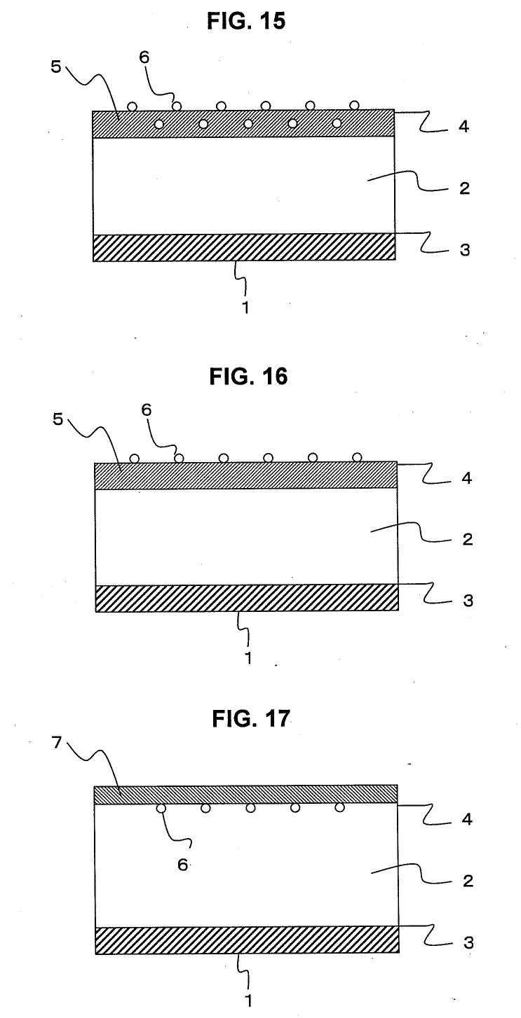

As illustrated in FIG. 15, silicon semiconductor substrate 2 was prepared, in which the DRAM is formed as semiconductor element 1 on main surface 3, and by using the grinding whetstone having Cu content of 1000 ppm, back side 4 of silicon semiconductor substrate 2 was roughly ground and was finishing-ground. Meanwhile, in FIG. 15, semiconductor element 1 is typically illustrated in a layered form. After this finishing-grinding, back side 4 of silicon semiconductor substrate 2 passing through the Cu-contained transport part was analyzed by the Raman spectroscopic analysis and the total reflection X ray fluorescence analysis. Meanwhile, the present compared example 1 is different from the producing method of exemplary embodiment 1 in the following points: (1) The Cu content of the whetstone for the grinding is 1000 ppm; (2) The cleaning step for silicon semiconductor substrate 2 passing through the transport part is not included; and (3) Thin film 7 for protecting the grinding surface of silicon semiconductor substrate 2 is not included.

As a result of the analysis, grinding damage 5 having depth of several dozen nm to several hundred nm was included in back side 4 of silicon semiconductor substrate 2. The Cu content of this grinding damage 5 area (area of depth of several dozen nm to several hundred nm from back side 4) was 1×10¹⁷/cm³ to 1×10¹⁸/cm³.

The refresh characteristic of the final product was estimated, which was obtained by packaging silicon semiconductor substrate 2 in such a condition. As a result of the estimation, the defective rate of the semiconductor chip, in which the refresh fault was induced, is around 50 ppm, so that the product yield was bad.

### Compared Example 2

As illustrated in FIG. 16, silicon semiconductor substrate 2 was prepared, in which the DRAM was formed as semiconductor element 1 on main surface 3, and by using the grinding whetstone having Cu content of 0.5 ppm, back side 4 of silicon semiconductor substrate 2 was roughly ground and was finishing-ground. Meanwhile, in FIG. 16, semiconductor element 1 is typically illustrated in a layered form. After this finishing-grinding, back side 4 of silicon semiconductor substrate 2 passing through the Cu-contained transport part was analyzed by the Raman spectroscopic analysis and the total reflection X ray fluorescence analysis. Meanwhile, the present compared example 2 is different from the producing method of exemplary embodiment 1 in the following points: (1) The cleaning step for silicon semiconductor substrate 2 passing through the transport part is not included; and (2) Thin film 7 for protecting the grinding surface of silicon semiconductor substrate 2 is not included.

As a result of the analysis, grinding damage 5 having depth of several dozen nm to several hundred nm from back side 4 of silicon semiconductor substrate 2, was included. The Cu content was 1×10¹⁵/cm³ to 1×10¹⁶/cm³.

The refresh characteristic of the final product is estimated, which was obtained by packaging silicon semiconductor substrate 2 under such a condition. As a result of the estimation, the defective rate of the semiconductor chip, in which the refresh fault was induced, was around 20 ppm, so that the product yield was bad.

### Compared Example 3

As illustrated in FIG. 17, silicon semiconductor substrate 2 was prepared, in which the DRAM was formed as semiconductor element 1 on main surface 3, and by using the grinding whetstone having Cu content of 1000 ppm, back side 4 of silicon semiconductor substrate 2 was roughly ground and was finishing-ground. Meanwhile, in FIG. 17, semiconductor element 1 is typically illustrated in a layered form. Next, after the polishing finishing-grinding was executed by using the normal grinding buff, thin film 7 made of the silicon nitride film was formed in back side 4 of silicon semiconductor substrate 2. Back side 4 of silicon semiconductor substrate 2 passing through the transport part was analyzed by the Raman spectroscopic analysis and the total reflection X ray fluorescence analysis. Meanwhile, the present compared example 3 is different from the producing method of exemplary embodiment 2 in the following points: (1) The Cu content of the whetstone is 1000 ppm; and (2) the chelated grinding buff is not used for the grinding buff used as the polishing finishing-grinding.

As a result of the analysis, grinding damage 5 was not included in back side 4 of silicon semiconductor substrate 2. However, Cu having content of 1×10¹⁰/cm² to 1×10¹¹/cm² was segregated in thin film 7 and back side 4 of silicon semiconductor substrate 2. This is because, since the normal grinding buff is used for the polishing finishing-grinding, the Cu contamination can not be completely eliminated, which is transcribed from the grinding whetstone to the inside of silicon semiconductor substrate 2 in the previous grinding.

The refresh characteristic of the final product is estimated, which was obtained by packaging silicon semiconductor substrate 2 under such a condition. As a result of the estimation, the defective rate of the semiconductor chip, in which the refresh fault was induced, was around 100 ppm, so that the product yield was bad.

It is apparent that the present invention is not limited to the above embodiments, but may be modified and changed without departing from the scope and spirit of the invention.

What is claimed is:

1. A method for producing a semiconductor device, comprising:
(1) preparing a silicon semiconductor substrate comprising a semiconductor element in one side;
(2) roughly grinding from a back side of the silicon semiconductor substrate being an opposite side of a side in which the semiconductor element is formed, by using a whetstone having a copper content of less than 1 ppm;
(3) finishing-grinding from the back side of the silicon semiconductor substrate, by using a whetstone having a copper content of less than 1 ppm;
(4) performing a silicon chemical etching-cleaning to the back side of the silicon semiconductor substrate;
(5) forming a silicon nitride film or a silicon oxynitride film by executing a heating process or a plasma process at 200° C. or less in ambient atmosphere including at least nitrogen or ammonia for the back side of the silicon semiconductor substrate; and
(6) dicing the silicon semiconductor substrate to form a semiconductor chip, and packaging the diced semiconductor chip.

2. The method for producing a semiconductor device according to claim 1, further comprising between the steps (3) and (4):
performing a polishing finishing-grinding to the back side of the silicon semiconductor substrate by using a grinding buff obtained by adding oxidized metal to chelated grinding buff and hardening the chelated grinding buff.

3. A method for producing a semiconductor device, comprising:
(1) preparing a silicon semiconductor substrate comprising a semiconductor element in one side;
(2) roughly grinding from a back side of the silicon semiconductor substrate being an opposite side of a side in which the semiconductor element is formed, by using a whetstone having a copper content of less than 1 ppm;
(3) finishing-grinding from the back side of the silicon semiconductor substrate, by using a whetstone having a copper content of less than 1 ppm;
(4) performing a polishing finishing-grinding to the back side of the silicon semiconductor substrate by using a grinding buff obtained by adding oxidized metal to chelated grinding buff and hardening the chelated grinding buff.
(5) forming a silicon nitride film or a silicon oxynitride film by executing a heating process or a plasma process at 200° C. or less in ambient atmosphere including at least nitrogen or ammonia for the back side of the silicon semiconductor substrate; and
(6) dicing the silicon semiconductor substrate to be a semiconductor chip, and packaging the diced semiconductor chip.

4. A method for producing a semiconductor device, comprising:
(1) preparing a silicon semiconductor substrate comprising a semiconductor element in one side;
(2) roughly grinding from a back side of the silicon semiconductor substrate, the back side being an opposite side of a side in which the semiconductor element is formed;
(3) finishing-grinding from the back side of the silicon semiconductor substrate;
(4) performing a silicon chemical etching-cleaning to the back side of the silicon semiconductor substrate so that a part up to depth of 3 nm from the back side of the silicon semiconductor substrate comprises a copper of 1×10⁹/cm² or less;
(5) forming a silicon nitride film or a silicon oxynitride film by executing a heating process or a plasma process at 200° C. or less in ambient atmosphere including at least nitrogen or ammonia for the back side of the silicon semiconductor substrate; and
(6) dicing the silicon semiconductor substrate to form a semiconductor chip, and packaging the diced semiconductor chip.

5. The method for producing a semiconductor device according to claim 4, further comprising between the steps (3) and (4):
performing a polishing finishing-grinding to the back side of the silicon semiconductor substrate by using a grinding buff obtained by adding oxidized metal to chelated grinding buff and hardening the chelated grinding buff.

6. A method for producing a semiconductor device, comprising:
(1) preparing a silicon semiconductor substrate comprising a semiconductor element in one side;
(2) roughly grinding from a back side of the silicon semiconductor substrate, the back side being an opposite side of a side in which the semiconductor element is formed;
(3) finishing-grinding from the back side of the silicon semiconductor substrate;
(4) performing a polishing finishing-grinding to the back side of the silicon semiconductor substrate, by using a grinding buff obtained by adding oxidized metal to chelated grinding buff and hardening the chelated grinding buff so that a part up to depth of 3 nm from the back side of the silicon semiconductor substrate comprises a copper of 1×10⁹/cm² or less;
(5) forming a silicon nitride film or a silicon oxynitride film by executing a heating process or a plasma process at 200° C. or less in ambient atmosphere including at least nitrogen or ammonia for the back side of the silicon semiconductor substrate; and
(6) dicing the silicon semiconductor substrate to form a semiconductor chip, and packaging the diced semiconductor chip.

7. A semiconductor device produced by the method for producing a semiconductor device according to claim 1.

8. The semiconductor device according to claim 7,
wherein the semiconductor chip comprises a grinding damage in the back side of the semiconductor chip, the back side being an opposite side of a side in which the semiconductor element is formed.

9. The semiconductor device according to claim 7,
wherein the semiconductor chip does not comprise a grinding damage in the back side of the semiconductor chip, the back side being an opposite side of a side in which the semiconductor element is formed.

10. A semiconductor device produced by the method for producing a semiconductor device according to claim 3.

11. The semiconductor device according to claim 10,
wherein the semiconductor chip comprises a grinding damage in the back side of the semiconductor chip, the back side being an opposite side of a side in which the semiconductor element is formed.

12. The semiconductor device according to claim 10,
wherein the semiconductor chip does not comprise a grinding damage in the back side of the semiconductor chip, the back side being an opposite side of a side in which the semiconductor element is formed.

13. A semiconductor device produced by the method for producing a semiconductor device according to claim 4.

14. The semiconductor device according to claim 13,
wherein the semiconductor chip comprises a grinding damage in the back side of the semiconductor chip, the back side being an opposite side of a side in which the semiconductor element is formed.

15. The semiconductor device according to claim 13,
wherein the semiconductor chip does not comprise a grinding damage in the back side of the semiconductor chip, the back side being an opposite side of a side in which the semiconductor element is formed.

16. A semiconductor device produced by the method for producing a semiconductor device according to claim 6.

17. The semiconductor device according to claim 16,
wherein the semiconductor chip comprises a grinding damage in the back side of the semiconductor chip, the back side being an opposite side of a side in which the semiconductor element is formed.

18. The semiconductor device according to claim 16,
wherein the semiconductor chip does not comprise a grinding damage in the back side of the semiconductor chip, the back side being an opposite side of a side in which the semiconductor element is formed.
